(19) United States
(12) Patent Application Publication
(10) Pub. No.: US 2026/0361045 A1
(43) Pub. Date: Nov. 12, 2026

(54) RECIPROCAL LINEAR FIT METHODOLOGY FOR CALIBRATING FREQUENCY LOCKER

(71) Applicant: Lumentum Technology UK Limited, NORTHAMPTONSHIRE (GB)

(72) Inventors: Yunhua XU, Shenzhen (CN); Fenhong ZHOU, Shenzhen (CN); Zhangkao SUN, Shenzhen (CN)

(21) Appl. No.: 19/130,436

(22) PCT Filed: Nov. 17, 2023
(86) PCT No.: PCT/CN2023/132313

§ 371 Date: May 15, 2025

(30) Foreign Application Priority Data
Sep. 11, 2023 (WO) PCT/CN2023/118110

(51) Int. Cl. H01S 3/13; G01J 3/26; G01J 3/45

(52) U.S. Cl. CPC H01S 3/1305; G01J 3/26; G01J 3/45

(57) ABSTRACT

A frequency locker calibration system (200) includes a detector (208) that measures a lock ratio of an interferometer (206) that is characterized by a frequency transfer curve; and a calibration circuit (212) that adjusts a frequency of a monitored light beam to estimate the frequency transfer curve based on the lock ratio. Estimating the frequency transfer curve includes sweeping the frequency of the monitored light beam to determine a peak frequency value and a bottom frequency value of the frequency transfer curve, calculating a free spectral range (FSR) and an offset value of the frequency transfer curve based on the peak frequency value and the bottom frequency value, calculating frequency fit values based on the FSR and the offset value, calculating reciprocal values of the maximum lock ratio and the minimum lock ratio, and calculating a set of fit factor parameters of a line using the frequency fit values and the reciprocal values.

### CROSS-REFERENCE TO RELATED APPLICATION

This Patent application claims priority to Patent Cooperation Treaty (PCT) Patent Application No. PCT/CN2023/118110, filed on Sep. 11, 2023, and entitled “RECIPROCAL LINEAR FIT METHODOLOGY FOR WAVELENGTH LOCKER.” The disclosure of the prior Application is considered part of and is incorporated by reference into this Patent Application.

### TECHNICAL FIELD

The present disclosure relates generally to frequency locker calibration systems and methods for calibrating a frequency locker.

### BACKGROUND

An etalon may be used as a locker optics element. The etalon, also known as a Fabry-Pérot interferometer, is a monolithic interferometric device containing two parallel reflecting surfaces. For example, the etalon may include parallel mirrors and may be used as a narrow band wavelength filter in laser applications (e.g., a resulting optical transmission or reflection of the etalon is periodic in wavelength). Optical waves can pass through an optical cavity formed between the two parallel reflecting surfaces only when the optical waves are in resonance with the etalon. When inserted into a laser beam, the etalon acts as an optical resonator (cavity), where a transmissivity varies approximately periodically with an optical wavelength (or frequency). In resonance, reflections from the two parallel reflecting surfaces cancel each other via destructive interference. A highest reflection loss (e.g., a lowest transmissivity) occurs in anti-resonance. The transmissivity versus wavelength can be described with a frequency response (e.g., a frequency transfer curve, an etalon transfer function, or an etalon transfer curve). An Airy function is one type of etalon transfer function. The etalon can therefore be used as an optical filter for tuning a frequency (or wavelength) of a laser to lock the frequency (or wavelength) of the laser at a desired frequency (or wavelength).

### SUMMARY

In some implementations, a frequency locker calibration system includes at least one light source configured to generate a first light beam; a beam splitter configured to split the first light beam into a first monitored light beam, comprising a first portion of the first light beam, and a first reference light beam, comprising a second portion of the first light beam; an optical filter comprising a first etalon characterized by a first etalon transfer curve, wherein the first etalon transfer curve comprises a first plurality of resonant peak frequencies at which a first transmittivity of the first etalon is at a first maximum transmission level, and a first plurality of minimum resonant frequencies at which the first transmittivity of the first etalon is at a first minimum transmission level, wherein the first etalon is configured to receive the first monitored light beam and output the first monitored light beam as a first monitored output light beam according to the first etalon transfer curve; a detector configured to measure a first monitored intensity of the first monitored output light beam and a first reference intensity of the first reference light beam, and determine a first lock ratio representative of a ratio of the first monitored intensity and the first reference intensity; and a calibration circuit, comprising at least one processor, configured to control the at least one light source to adjust a frequency of the first light beam to estimate the first etalon transfer curve based on the first lock ratio, wherein the calibration circuit is configured to: sweep the frequency of the first light beam for determining a first peak frequency value corresponding to a first maximum lock ratio of the first etalon transfer curve, and for determining a first bottom frequency value corresponding to a first minimum lock ratio of the first etalon transfer curve, perform a first reciprocal linear fit calculation to calculate a first set of fit factor parameters of a first line based on the first peak frequency value and the first bottom frequency value, and store the first set of fit factor parameters, wherein the first set of fit factor parameters correspond to a first slope of the first etalon transfer curve.

In some implementations, a frequency locker calibration system includes a detector configured to measure a lock ratio of an interferometer, wherein the lock ratio is representative of a ratio of a monitored intensity of a monitored light beam that interacts with the interferometer and a reference intensity of a reference light beam that bypasses the interferometer, and wherein the interferometer is characterized by a frequency transfer curve; and a calibration circuit configured to adjust a frequency of the monitored light beam to estimate the frequency transfer curve based on the lock ratio, wherein the calibration circuit is configured to: sweep the frequency of the monitored light beam to determine a peak frequency value corresponding to a maximum lock ratio of the frequency transfer curve, and to determine a bottom frequency value corresponding to a minimum lock ratio of the frequency transfer curve, perform a reciprocal linear fit calculation to calculate a set of fit factor parameters of a line based on the peak frequency value and the bottom frequency value, and store the set of fit factor parameters, wherein the set of fit factor parameters correspond to a slope of the frequency transfer curve.

In some implementations, a method of estimating a frequency transfer curve of an interferometer includes measuring a lock ratio of an interferometer, wherein the lock ratio is representative of a ratio of a monitored intensity of a monitored light beam that interacts with the interferometer and a reference intensity of a reference light beam that bypasses the interferometer, and wherein the interferometer is characterized by the frequency transfer curve; adjusting the frequency of the monitored light beam to estimate the frequency transfer curve based on the lock ratio, including sweeping the frequency of the monitored light beam to determine a peak frequency value corresponding to a maximum lock ratio of the frequency transfer curve, and to determine a bottom frequency value corresponding to a minimum lock ratio of the frequency transfer curve; executing a reciprocal linear fit calculation to calculate a set of fit factor parameters of a line based on the peak frequency value and the bottom frequency value; and storing the set of fit factor parameters, wherein the set of fit factor parameters correspond to a slope of the frequency transfer curve.

### BRIEF DESCRIPTION OF THE DRAWINGS

FIG. 1 shows a stepped etalon according to one or more implementations.

FIG. 2 shows a frequency locker calibration system according to one or more implementations.

FIG. 3 shows a diagram of etalon transfer curves for a stepped etalon according to one or more implementations.

FIG. 4 shows an etalon transfer curve corresponding to a stepped etalon calibration method according to one or more implementations.

FIG. 5 shows a graph of a reciprocal linear fit method of the stepped etalon calibration method according to one or more implementations.

FIG. 6 shows a stepped etalon frequency response.

FIG. 7 shows a graph of a lock frequency accuracy resultant from the stepped etalon transfer curve with ripple generated using a traditional fit calibration method.

FIG. 8 shows a graph of a lock frequency accuracy resultant from performing a calibration operation that uses the stepped etalon calibration method with the reciprocal linear fit method.

FIG. 9 is a flowchart of an example process associated with a reciprocal linear fit methodology for calibrating a frequency locker.

### DETAILED DESCRIPTION

The following detailed description of example implementations refers to the accompanying drawings. The same reference numbers in different drawings may identify the same or similar elements.

Traditional frequency lock solutions are unable to realize low-power dissipation flex grid frequency tuning. For example, a single etalon cannot be used for flex grid frequency tuning. A thermal etalon is capable for flex grid frequency tuning but requires additional power dissipation to control an etalon temperature. Meanwhile, a tuning speed of the thermal etalon is slower than the single etalon. A stepped etalon is one of a new generation of etalons for flex grid tuning with low-power dissipation and a rapid response.

A stepped etalon includes a transparent body having a stepped surface. The stepped surface has a stepped transition from one portion of the stepped surface to a second portion of the stepped surface. The stepped etalon may have a body which is transparent at least in a predetermined range of wavelengths and having a first side and a second side arranged opposite to the first side. The first side may be a flat surface. The second side may be a stepped surface having one or more steps, with each step having a flat land substantially parallel to the flat surface of the first side. Thus, the stepped surface provides multiple regions of different thicknesses relative to the first side and the second side. Each step on the etalon provides a region of a different thickness. By adjusting the thicknesses appropriately, each step can be configured to pass different frequencies of light.

When the stepped etalon is used for frequency-locking for a flex grid frequency application, a high-accuracy etalon transfer curve fitting function is needed. In real fit function development, achieving the high-accuracy etalon transfer curve fitting function can be very challenging when a locked beam contains many light ripples (e.g., multiple source optical ripples), such as multi-source reflections. In addition, achieving the high-accuracy etalon transfer curve fitting function can be very challenging due to manufacturing variables, such as reflectivity, refractive index, and thickness, caused by non-ideal etalon fabrication (e.g., manufacturing errors).

Traditional fit methods use one formula calculation for estimating an etalon transfer function (e.g., an etalon transfer curve or a frequency transfer curve) across an entire etalon band, which may correspond to an Airy function and may contain many error correction factors. For example, a standard etalon transfer function may correspond to the Airy function and may be fitted to an ideal Airy curve. However, in practical applications, additional noise or optical ripple effects may exist, which can be difficult to remove. A frequency-locking performance of an etalon may be diminished and rendered unsatisfactory if a frequency locker is calibrated with a low-accuracy fitting method. Feasibility studies with the traditional fit methods show poor performance in terms of a fitting function and frequency-locking accuracy. In other words, traditional fit methods provide a poor estimate of the etalon transfer function of a stepped etalon for the entire etalon band. As a result, accurate frequency-locking with the stepped etalon cannot be achieved. While the stepped etalon has become a promising component in the next generation of high-performance flex grid frequency-locking products, the stepped etalon cannot be used with a degree of accuracy required until an etalon transfer curve calibration and fit method is developed that provides an accurate estimation of the etalon transfer function across the entire etalon band.

Some implementations disclosed herein provide an etalon calibration method that is used to provide a high-performance frequency-locking device with high-accuracy fitting to an etalon transfer curve and low-error frequency-locking. Furthermore, compared with a traditional frequency-locking scheme, the etalon calibration method is capable of being performed at a manufacturing scale, and a calibration test time is greatly shortened. Thus, a high-performance method for stepped etalon calibration used in flex grid wavelength locking products is provided.

The etalon calibration method may be performed to obtain a high-accuracy fitting function through a reasonable calibration test time, so as to achieve high-performance frequency-locking. The etalon calibration method may be used for calibrating frequency-locking systems and devices that use a stepped etalon as a frequency lock component. Thus, the etalon calibration method may overcome challenges in achieving a high-accuracy frequency lock in stepped etalon applications.

A stepped etalon calibration method disclosed herein may improve the frequency-locking performance of a frequency locker (e.g., a wavelength locker) with a stepped etalon, through two aspects of development. First, the stepped etalon calibration method includes separately estimating each etalon slope of an entire band etalon curve, instead of attempting to estimate the entire band etalon curve with one fitting calculation. Thus, the stepped etalon calibration method includes different fitting functions for different etalon slopes to provide improved accuracy. Second, the stepped etalon calibration method includes transforming a sinusoidal-likelihood transfer curve into a straight line through reciprocal processing for estimating each etalon slope of the entire band etalon curve. The stepped etalon calibration method is a controllable and manufacturable test solution for determining a high-accuracy fitting function to be used for achieving a high-accuracy frequency-locking for stepped etalon applications. In addition, the stepped etalon calibration method expands the applications for which the stepped etalon may be used to any product with flex grid wavelength-locking requirements, such as a 128G transmitter receiver optical sub-assembly (TROSA), a 64G SiP TROSA, and all other tunable products, including coherent transceivers with a flex grid frequency-locking function.

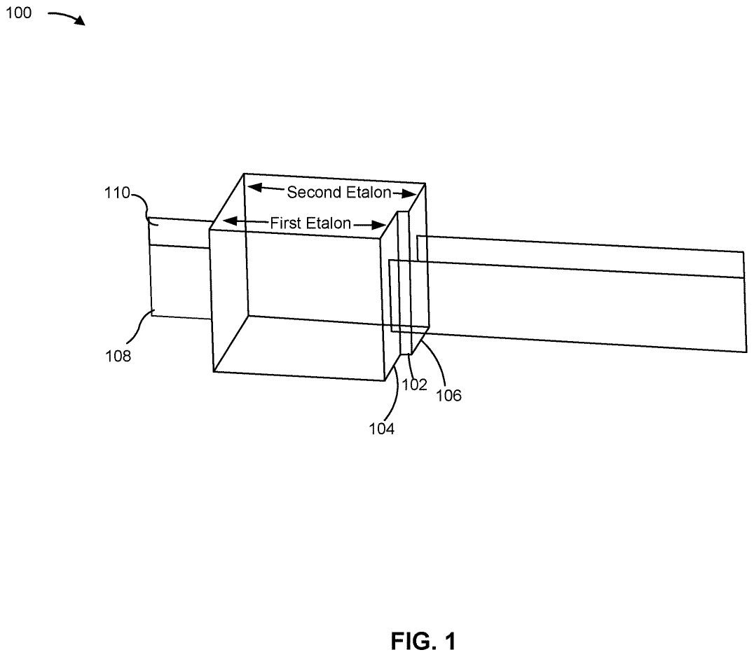

FIG. 1 shows a stepped etalon 100 according to one or more implementations. The stepped etalon 100 may be configured to receive light at a receiving side (e.g., a left side) and transmit light from a transmitting side (e.g., a right side). In some cases, light is reflected within the stepped etalon 100 and transmitted back out of the receiving side. The receiving side has a single flat surface, whereas the transmitting side has a stepped surface with one stepped transition edge 102 that transitions from a first flat land 104 (e.g., a first stepped portion) to a second flat land 106 (e.g., a second stepped portion). Thus, the first flat land 104 has a first distance from the receiving side to define a first thickness, and the second flat land 106 has a second distance from the receiving side to define a second thickness.

The stepped etalon 100 may be referred to as an optical filter that has a first etalon corresponding to the first flat land 104 and a second etalon corresponding to the second flat land 106. The first etalon and the second etalon may be configured to pass different frequencies of light according to different etalon transfer curves. For example, the first etalon may be characterized by a first etalon transfer curve and the second etalon may be characterized by a second etalon transfer curve that is different from the first etalon transfer curve. Thus, for a same frequency, the first etalon and the second etalon may provide different lock ratios. A lock ratio is a ratio of a light intensity of a monitored light beam that interacts with an etalon versus a light intensity of a reference light beam that bypasses the etalon.

The first etalon may be configured to receive a first light beam 108 at the receiving side and transmit the first light beam 108 at the transmitting side. The first light beam 108 may have a light intensity that depends on the first etalon transfer curve. For example, the light intensity of the first light beam 108 at the transmitting side may depend on a frequency of the first light beam 108 relative to the first etalon transfer curve. Thus, the first light beam 108 may have different light intensities at the transmitting side for different frequencies according to the first etalon transfer curve.

The second etalon may be configured to receive a second light beam 110 at the receiving side and transmit the second light beam 110 at the transmitting side. The second light beam 110 may have a light intensity that depends on the second etalon transfer curve. For example, the light intensity of the second light beam 110 at the transmitting side may depend on a frequency of the second light beam 110 relative to the second etalon transfer curve. Thus, the second light beam 110 may have different light intensities at the transmitting side for different frequencies according to the second etalon transfer curve.

As indicated above, FIG. 1 is provided as an example. Other examples may differ from what is described with regard to FIG. 1.

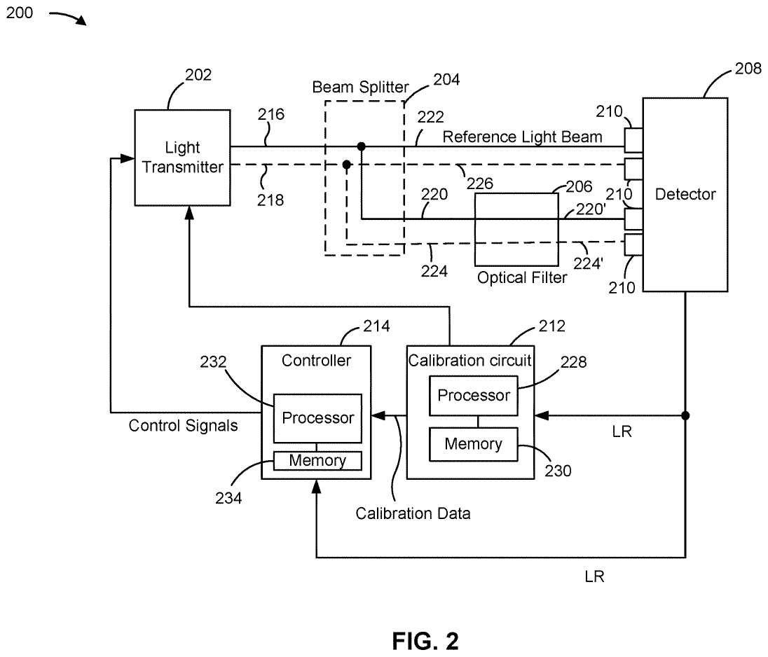

FIG. 2 shows a frequency locker calibration system 200 according to one or more implementations. The frequency locker calibration system 200 may include a light transmitter 202, a beam splitter 204, an optical filter 206, a detector 208 that includes a plurality of photodetectors 210, a calibration circuit 212, and a controller 214. The optical filter 206 may be an interferometer defined by a frequency transfer curve. For example, the optical filter 206 may be an etalon that is characterized by an etalon transfer curve. In some implementations, the optical filter 206 may be a stepped etalon that includes a first etalon characterized by a first etalon transfer curve and a second etalon characterized by a second etalon transfer curve as similarly described in connection with FIG. 1.

The light transmitter 202 may include at least one light source configured to generate one or more light beams transmitted toward the optical filter 206. Each light beam may be a collimated light beam. Thus, in some implementations, each light source may include a collimator. In some implementations, the light transmitter 202 may generate a first light beam 216 for the first etalon of the stepped etalon and may generate a second light beam 218 for the second etalon of the stepped etalon. The first light beam 216 and the second light beam 218 may be generated by a same light source or by different light sources of the light transmitter 202. Frequencies of the first light beam 216 and the second light beam 218 may be controlled by the controller 214 via control signals. For example, the light transmitter 202 may generate the first light beam 216 at a frequency (e.g., a first frequency) that may be varied at different frequency values to perform a calibration operation for the first etalon, and the light transmitter 202 may generate the second light beam 218 at a frequency (e.g., a second frequency) that may be varied at different frequency values to perform a calibration operation for the second etalon.

The beam splitter 204 may split the first light beam 216 into a first monitored light beam 220, comprising a first portion of the first light beam 216, and a first reference light beam 222, comprising a second portion of the first light beam 216. In other words, the beam splitter 204 may split the first light beam 216 into two portions. In some implementations, the beam splitter 204 may be a 50:50 power beam splitter such that an optical power of the first monitored light beam 220 and an optical power of the first reference light beam 222 are both 50% of an optical power of the first light beam 216. Similarly, the beam splitter 204 may split the second light beam 218 into a second monitored light beam 224, comprising a first portion of the second light beam 218, and a second reference light beam 226, comprising a second portion of the second light beam 218.

The first etalon transfer curve may be referred to as an optical frequency response function or an etalon transfer function of the first etalon. In some implementations, the first etalon transfer curve may be modeled by an Airy function. A transmittivity (or a reflectivity) of the first etalon depends on the frequency of the first light beam 216 relative to the first etalon transfer curve. In other words, the transmittivity (or the reflectivity) of the first etalon varies as a function of the frequency of the first light beam 216. An intensity of light transmitted through or output by the first etalon corresponds to the transmittivity of the first etalon that is dictated by where the frequency of the first light beam 216 is located on the first etalon transfer curve. Similarly, an intensity of light transmitted through or output by the second etalon corresponds to the transmittivity of the second etalon that is dictated by where the frequency of the second light beam 218 is located on the second etalon transfer curve.

The first etalon transfer curve may include a first plurality of resonant peak frequencies at which a first transmittivity of the first etalon is at a first maximum transmission level, and a first plurality of minimum resonant frequencies at which the first transmittivity of the first etalon is at a first minimum transmission level. Thus, the first etalon may receive the first monitored light beam 220 and output the first monitored light beam 220 as a first monitored output light beam 220′ according to the first etalon transfer curve (e.g., based on the frequency of the first monitored light beam 220). The second etalon transfer curve may include a second plurality of resonant peak frequencies at which a second transmittivity of the second etalon is at a second maximum transmission level, and a second plurality of minimum resonant frequencies at which the second transmittivity of the second etalon is at a second minimum transmission level. In addition, the second etalon transfer curve may have a peak frequency offset relative to the first etalon transfer curve. In other words, the second etalon transfer curve may be phase shifted relative to the first etalon transfer curve such that the second plurality of resonant peak frequencies are shifted from the first plurality of resonant peak frequencies. The peak frequency offset or phase shift may provide a usable transmission versus frequency slope across an entire frequency band of the optical filter 206. The second etalon may receive the second monitored light beam 224 and output the second monitored light beam 224 as a second monitored output light beam 224′ according to the second etalon transfer curve (e.g., based on the frequency of the second monitored light beam 224).

The detector 208 may be configured to measure a first monitored intensity of the first monitored output light beam 220′ and a first reference intensity of the first reference light beam, and determine a first lock ratio (LR) representative of a ratio of the first monitored intensity and the first reference intensity (e.g., the first monitored intensity/the first reference intensity). For example, the photodetectors 210 may measure an intensity of light and generate electrical signals that are proportional to the intensity of light. The detector 208 may include processing circuitry (e.g., transimpedance amplifiers and differential amplifiers) configured to determine a lock ratio based on a respective monitored intensity and a respective reference intensity. The detector 208 may be further configured to measure a second monitored intensity of the second monitored output light beam 224′ and a second reference intensity of the second reference light beam 226, and determine a second lock ratio representative of a ratio of the second monitored intensity and the second reference intensity (e.g., the second monitored intensity/the second reference intensity).

The calibration circuit 212 may include a processor 228 and a memory device 230 that are used to perform one or more calibration operations based on the first lock ratio corresponding to the first etalon and/or based on the second lock ratio corresponding to the second etalon. In some implementations, the calibration circuit 212 may include or may be integrated with a controller to control the at least one of the light sources of the light transmitter 202 to adjust the frequency of the first light beam 216 to estimate the first etalon transfer curve based on the first lock ratio. In addition, the calibration circuit 212 may be configured to control the at least one of the light sources of the light transmitter 202 to adjust the frequency of the second light beam 218 to estimate the second etalon transfer curve based on the second lock ratio.

In some implementations, the calibration circuit 212 may be integrated with the controller 214. In some implementations, the calibration circuit 212 may transmit control signals to control the at least one light source of the light transmitter 202. In some implementations, the calibration circuit 212 may use the controller 214 to transmit the control signals to control the at least one light source of the light transmitter 202. In some implementations, the calibration circuit 212 may calibrate the controller 214 with the first etalon transfer curve or with calibration information corresponding to the first etalon transfer curve such that the controller 214 may be used to perform a frequency lock operation relative to the first etalon. In some implementations, the memory device 230 may store the calibration information corresponding to the first etalon transfer curve, which may then be provided to the controller 214 for the frequency lock operation relative to the first etalon. In some implementations, the calibration circuit 212 may calibrate the controller 214 with the second etalon transfer curve with calibration information corresponding to the second etalon transfer curve such that the controller 214 may be used to perform a frequency lock operation relative to the second etalon. In some implementations, the memory device 230 may store the calibration information corresponding to the second etalon transfer curve, which may then be provided to the controller 214 for the frequency lock operation relative to the second etalon. The calibration circuit 212 may be configured to calculate the calibration information by using a reciprocal linear fit algorithm. For example, the calibration circuit 212 may be configured to perform a reciprocal linear fit calculation based on the reciprocal linear fit algorithm to calculate one or more sets of fit factor parameters that may be used to calibrate the controller 214.

For example, using the calibration information for the first etalon, the controller 214 may, during a frequency lock operation, tune the frequency of the first light beam 216 to a first target frequency value based on the first lock ratio such that a difference between the first lock ratio (e.g., a measured lock ratio) and a first target lock ratio corresponding to the first target frequency value is minimized. Similarly, using the calibration information for the second etalon, the controller 214 may, during a frequency lock operation, tune the frequency of the second light beam 218 to a second target frequency value based on the second lock ratio such that a difference between the second lock ratio (e.g., a measured lock ratio) and a second target lock ratio corresponding to the second target frequency value is minimized.

Accordingly, the controller 214 may be configured to lock the frequency of the first light beam 216 to the first target frequency, and/or lock the frequency of the second light beam 218 to the second target frequency during one or more frequency lock operations performed after calibration (e.g., performed after one or more of the first etalon transfer curve and/or the second etalon transfer curve are estimated). The controller 214 may include a processor 232 (or other processing circuitry) and a memory device 234 that are used to perform one or more frequency lock operations. For example, the memory device 234 may be configured to store the calibration information received from the calibration circuit 212, and the processor 232 may be configured to use the calibration information for performing one or more frequency lock operations (e.g., for generating one or more control signals).

An etalon transfer function may be defined by an Airy function according to Equation 1:

$$LR = \frac{A}{1 + F \cdot [ sin ( k \cdot f + p ) ] \hat{} 2} , \qquad Eq . 1$$

where LR denotes the lock ratio that defines the etalon transfer curve,

$$k = \frac{π}{FSR} ,$$

f is a frequency, p is a phase of an etalon curve peak (e.g., a peak frequency value of an etalon transfer curve) versus the FSR, A is a maximum LR value of the etalon transfer curve (e.g., a maximum amplitude), and F is a shape factor that defines a shape of the etalon transfer curve. The FSR is a difference, in wavelength or frequency, between two adjacent peaks or valleys of the etalon transfer curve. Equation 2 represents a reciprocal of Equation 1 (e.g., a reciprocal of LR):

$$\frac{1}{LR} = \frac{2 + F}{2 A} - \frac{F}{2 A} \cdot cos ( 2 kf + 2 p ) . \qquad Eq . 2$$

As described above, the first etalon transfer curve may include the first plurality of resonant peak frequencies at which a first transmittivity of the first etalon is at a first maximum transmission level, and the first plurality of minimum resonant frequencies at which the first transmittivity of the first etalon is at a first minimum transmission level. In other words, each resonant peak frequency corresponds to a maximum lock ratio of the first etalon transfer curve, and each minimum resonant frequency corresponds to a minimum lock ratio of the first etalon transfer curve. A resonant peak frequency may be referred to as a peak frequency value Fₚₑₐₖ and a minimum resonant frequency may be referred to as a bottom frequency value F_{bottom}.

Equations 3 and 4 define an offset value of an etalon transfer curve:

$$Offset = \frac{2 p}{π} ; \qquad Eq . 3 ,$$

$$Offset = 2 \cdot ( ( \frac{Fpeak}{FSR} ) - int ( \frac{Fpeak}{FSR} ) ) , \qquad Eq . 4$$

where, “int” is a rounding down function that rounds down a real number to a nearest integer (e.g., 5.2 is rounded down to 5). The FSR of an etalon transfer curve may be calculated based on Equation 5.

FSR=2·abs(Fₚₑₐₖ−F_{bottom}) Eq. 5,

where, “abs” is an absolute value function that calculates the absolute value of Fₚₑₐₖ−F_{bottom}.

A frequency fit value F_{fit} of an etalon transfer curve may be calculated based on Equation 6 or Equation 7:

$${F}_{fit} = cos ( \frac{2 \cdot π \cdot f}{FSR} + offset \cdot π ) , \qquad Eq . 6$$

$${F}_{fit} = cos ( \frac{2 \cdot π \cdot f}{FSR} + 2 p ) . \qquad Eq . 7$$

A linear fit equation (e.g., a line equation) may be provided according to Equations 8, 9, 10, and 11:

$$a = - \frac{F}{2 A} , \qquad Eq . 8$$

$$b = \frac{2 + F}{2 A} , \qquad Eq . 9$$

$${LR}_{fit} = a \cdot Ffit + b , \qquad Eq . 10$$

$$Y = a \cdot x + b , \qquad Eq . 11$$

where x represents the frequency fit value F_{fit} of a given frequency (e.g., x=F_{fit}), Y is a reciprocal value of LR (e.g., Y=1/LR), and “a” and “b” represent a set of fit factor parameters of a line represented by the line equation represented by Equation 11. For example, “a” may be a slope parameter representative of a slope of the line and “b” may be an intercept parameter representative of a y-axis intercept of the line. Variables Y and x can be determined for a particular frequency value, with each Y value and each x value corresponding to the particular frequency value. By determining Y and x for two or more frequency values, Equation 11 may be used to determine the set of fit factor parameters (a, b) for the line. Thus, a linear fit may be performed by x and Y to solve for the set of fit factor parameters (a, b). For example, the set of fit factor parameters (a, b) may be calculated based on Equation 11, at least two values for Y, and at least two values for x. The line may correspond to one slope of an etalon transfer curve. Thus, each set of fit factor parameters (a, b) may correspond to one slope of the etalon transfer curve. A different set of fit factor parameters (a, b) may be calculated for each slope of the etalon transfer curve in order to estimate the etalon transfer curve for an entire etalon band (e.g., frequency band) of an etalon. In other words, the entire etalon transfer curve may be estimated by calculating the set of fit factor parameters (a, b) for each slope of the etalon transfer curve. The sets of fit factor parameters (a, b) may be stored in the memory device 230 and/or the memory device 234 as the calibration information to be used for a frequency lock operation.

The calibration circuit 212 (e.g., the processor 228 of the calibration circuit 212) may sweep the frequency of the first light beam 216 for determining a first peak frequency value Fₚₑₐₖ₁ corresponding to a first maximum lock ratio of the first etalon transfer curve, and for determining a first bottom frequency value F_{bottom1} corresponding to a first minimum lock ratio of the first etalon transfer curve. For example, the calibration circuit 212 may control the light transmitter 202 to vary the frequency of the first light beam 216 until the lock ratio measured by the detector 208 is at a maximum value. The frequency of the first light beam 216 corresponding to the maximum value may be recorded as the first peak frequency value Fₚₑₐₖ₁. Similarly, the calibration circuit 212 may control the light transmitter 202 to vary the frequency of the first light beam 216 until the lock ratio measured by the detector 208 is at a minimum value. The frequency of the first light beam 216 corresponding to the minimum value may be recorded as the first bottom frequency value F_{bottom1}. The first peak frequency value Fₚₑₐₖ₁ and the first bottom frequency value F_{bottom1} may define a frequency range that corresponds to one slope of the first etalon transfer curve, with the first maximum lock ratio and the first minimum lock ratio corresponding to one half period of the first etalon transfer curve.

The calibration circuit 212 (e.g., the processor 228 of the calibration circuit 212) may use Equations 1-11 as a basis to perform a reciprocal linear fit calculation to calculate one or more sets of fit factor parameters that may be used as calibration information. For example, the calibration circuit 212 may use Equation 5 to calculate a first FSR of the first etalon transfer curve, and may use Equation 3 or 4 to calculate a first offset value of the first etalon transfer curve. For example, the calibration circuit 212 may calculate the first FSR of the first etalon transfer curve based on the first peak frequency value Fₚₑₐₖ₁ and the first bottom frequency value F_{bottom1}. In addition, the calibration circuit 212 may calculate the first offset value of the first etalon transfer curve based on first peak frequency value Fₚₑₐₖ₁ and the first FSR, which may be determined based on the first peak frequency value Fₚₑₐₖ₁ and the first bottom frequency value F_{bottom1}. Thus, both the first FSR and the first offset value of the first etalon transfer curve may be calculated based on the first peak frequency value Fₚₑₐₖ₁ and the first bottom frequency value F_{bottom1}. The calibration circuit 212 may use the first FSR and the first offset value for further calculations.

The calibration circuit 212 may calculate a first frequency fit value F_{fit1} based on the first peak frequency value Fₚₑₐₖ₁, the first FSR, and the first offset value in accordance with Equation 6, where frequency f is equal to the first peak frequency value Fₚₑₐₖ₁ (e.g., f=Fₚₑₐₖ₁). Additionally, the calibration circuit 212 may calculate a second frequency fit value F_{fit2} based on the first bottom frequency value F_{bottom1}, the first FSR, and the first offset value in accordance with Equation 6, where frequency f is equal to the first bottom frequency value F_{bottom1} (e.g., f=F_{bottom1}). Thus, a frequency fit value may be calculated for each frequency value determined in the frequency sweep.

In addition, the calibration circuit 212 may calculate a first reciprocal value Y₁ representative of a reciprocal of the first maximum lock ratio, and may calculate a second frequency fit value based on the first bottom frequency value, the first FSR, and the first offset value. Thus, the calibration circuit 212 may calculate a corresponding reciprocal value Y₂ for each frequency fit value F_{fit}, where each corresponding reciprocal value Y is associated with an LR of the frequency f used in Equation 6.

As a result of the calculations, the calibration circuit 212 has determined two values for x (e.g., F_{fit1} and F_{fit2}) and two values for Y (e.g., Y₁ and Y₂) that correspond to two measurement points (e.g., a peak point and a bottom point) on the first etalon transfer curve. Thus, Equation 11 can be solved for a set of fit factor parameters (a, b) using the two values for x and two values for Y. The calibration circuit 212 may calculate a first set of fit factor parameters (a₁, b₁) of a first line by performing a first linear fit to a line equation (e.g., a linear fit to Equation 11) using the first frequency fit value F_{fit1}, the first reciprocal value Y₁, the second frequency fit value F_{fit2}, and the second reciprocal value Y₂. The first line may be a line or an approximate line that connects the two measurement points of the first etalon transfer curve. Thus, the first set of fit factor parameters (a₁, b₁) includes a slope parameter a₁ representative of a slope of the first line and an intercept parameter b₁ representative of a y-axis intercept of the first line. Thus, the first set of fit factor parameters (a₁, b₁) correspond to a slope (e.g., a first slope) of the first etalon transfer curve.

The calibration circuit 212 may be configured to store the first set of fit factor parameters (a₁, b₁) in the memory device 230 and/or the memory device 234 as calibration information corresponding to the first etalon. For example, the calibration circuit 212 may store, into the memory device 230 and/or the memory device 234, the first set of fit factor parameters (a₁, b₁), the first FSR, the first offset value, and a frequency range defined by the first peak frequency value Fₚₑₐₖ₁ and the first bottom frequency value F_{bottom1} as linked parameters that correspond to the slope of the first etalon transfer curve.

The first set of fit factor parameters (a₁, b₁) may be used during a frequency lock operation of the first etalon. For example, the first set of fit factor parameters (a₁, b₁) may be used to determine a target lock ratio for a target frequency value F_{target}, and the target lock ratio may then be used by the controller 214 to perform the frequency lock operation. The target frequency value is located in the frequency range defined by the first peak frequency value Fₚₑₐₖ₁ and the first bottom frequency value F_{bottom1}.

During the frequency lock operation, the calibration circuit 212 or the controller 214 may calculate the target lock ratio for the target frequency value. The target frequency value F_{target} may be provided as an input variable. For example, the calibration circuit 212 may calculate a target frequency fit value F_{fitT} based on the target frequency value F_{target}, the first FSR, and the first offset value in accordance with Equation 6, where frequency f is equal to the target frequency value F_{target} (e.g., f=F_{target}). The calibration circuit 212 may calculate the target lock ratio based on the target frequency fit value F_{fitT} and the first set of fit factor parameters (a₁, b₁) according to Equation 11. For example, the target frequency fit value F_{fitT} (e.g., x=F_{fitT}) and the first set of fit factor parameters (a₁, b₁) may be used to solve for the reciprocal value Y, and the target lock ratio may be determined by calculating a reciprocal of the reciprocal value Y (e.g., Y=1/LR). Thus, the calibration circuit 212 may determine the target lock ratio of the target frequency value F_{target} from the reciprocal value Y calculated according to Equation 11.

Which variables to be used for the calculation of the target lock ratio (e.g., which set of fit factor parameters, which FSR, and which offset value) may be selected based on the frequency range in which the target frequency value F_{target} is located. In this example, the target frequency value F_{target} is located in the frequency range defined by the first peak frequency value Fₚₑₐₖ₁ and the first bottom frequency value F_{bottom1}. Thus, variables associated with this frequency range are used. If the target frequency value F_{target} is located in a different frequency range, variables associated with the different frequency range would be used by the calibration circuit 212 or the controller 214 for determining the target lock ratio. Thus, the calibration circuit 212 may be configured to calculate a corresponding set of fit factor parameters (a, b) for each slope of the first etalon transfer curve (e.g., for each slope between each pair of maximum and minimum LR values of the first etalon transfer curve), with each slope extending from a corresponding peak frequency value to a corresponding bottom frequency value. The calibration circuit 212 may store, into the memory device 230 and/or the memory device 234, each corresponding set of fit factor parameters (a, b) with a corresponding FSR, a corresponding offset value, and a corresponding frequency range as linked parameters that correspond to a respective slope of the first etalon transfer curve. For use in calculating the target lock ratio for a frequency lock operation, the calibration circuit 212 may look up the corresponding set of fit factor parameters (a, b), the corresponding FSR, and the corresponding offset value based on the corresponding frequency range in which the target frequency value F_{target} is located.

The controller 214 may use the target lock ratio for the frequency lock operation. For example, the controller 214 may monitor the first lock ratio received from the detector 208 during the frequency lock operation. During the frequency lock operation, the controller 214 may tune the frequency of the first light beam 216 to the target frequency value F_{target} based on the first lock ratio (e.g., the measured lock ratio) such that a difference between the first lock ratio and the target lock ratio is minimized.

When only two measurement points on an etalon transfer curve (e.g., a peak point and a bottom point) are used to calculate the line or the slope of the etalon transfer curve, the line is a first order line. However, one or more additional measurement points may be used to increase a robustness of a line fit estimation. For example, the additional measurement points may be desired to solve Equation 11 for “a” and “b” when the etalon transfer curve is noisy or has other irregularities. The one or more additional measurement points may be arbitrarily (e.g., randomly) selected by the calibration circuit 212. When one or more additional measurement points are used to calculate a set of fit factor parameters, the line may be referred to as a higher order line. For example, when one additional point is used, three measurement points in total are used to calculate the line or the slope of the etalon transfer curve. Thus, the line is a second order line. When two additional measurement points are used, four measurement points in total are used to calculate the line or the slope of the etalon transfer curve. Thus, the line is a third order line. A fourth order line is derived from five measurement points.

During a calibration operation, the calibration circuit 212 may select the frequency of the first light beam 216 to be between the first peak frequency value Fₚₑₐₖ₁ and the first bottom frequency value F_{bottom1} for use as an additional measurement point for estimating the first line of the first etalon transfer curve. For example, the calibration circuit 212 may set the frequency of the first light beam 216 to an intermediate frequency value Fint between the first peak frequency value Fₚₑₐₖ₁ and the first bottom frequency value F_{bottom1}. The calibration circuit 212 may measure the first lock ratio corresponding to the intermediate frequency value Fint as an intermediate lock ratio. The calibration circuit 212 may calculate an intermediate frequency fit value F_{fit_int} based on the intermediate frequency value Fint, the first FSR, and the first offset value, according to Equation 6. The calibration circuit 212 may calculate an intermediate reciprocal value Y₃ representative of a reciprocal of the intermediate lock ratio.

As a result of the calculations, the calibration circuit 212 has determined three values for x (e.g., F_{fit1}, F_{fit2}, and F_{fit_int}) and three values for Y (e.g., Y₁, Y₂, and Yᵢₙₜ) that correspond to three measurement points (e.g., a peak point, an intermediate point, and a bottom point) on the first etalon transfer curve. Thus, Equation 11 can be solved for a set of fit factor parameters (a, b) using the three values for x and three values for Y. The calibration circuit 212 may calculate the first set of fit factor parameters (a₁, b₁) of the first line by performing the first linear fit to the line equation (e.g., a linear fit to Equation 11) using the first frequency fit value F_{fit1}, the first reciprocal value Y₁, the second frequency fit value F_{fit2}, the second reciprocal value Y₂, the intermediate frequency fit value F_{fit_int}, and the intermediate reciprocal value Yᵢₙₜ. The first line may be a line or an approximate line that is best fitted to the three measurement points of the first etalon transfer curve. The calculation of the first set of fit factor parameters (a₁, b₁) may be adapted to account for additional measurement points by calculating an x value (e.g., a frequency fit value) and a Y value (e.g., a reciprocal LR value) for each additional measurement point, and performing a linear fit to the line equation using all x values and all Y values for a defined frequency range.

A calibration operation may be repeated for the second etalon to estimate the second etalon transfer curve. In other words, the entire second etalon transfer curve may be estimated by calculating the set of fit factor parameters (a, b) for each slope of the second etalon transfer curve. The sets of fit factor parameters (a, b) may be stored in the memory device 230 and/or the memory device 234 as the calibration information to be used for a frequency lock operation that uses the second etalon.

For example, the calibration circuit 212 (e.g., the processor 228 of the calibration circuit 212) may sweep the frequency of the second light beam 218 for determining a second peak frequency value Fₚₑₐₖ₂ corresponding to a second maximum lock ratio of the second etalon transfer curve, and for determining a second bottom frequency value F_{bottom2} corresponding to a second minimum lock ratio of the second etalon transfer curve. The calibration circuit 212 may calculate a second FSR of the second etalon transfer curve and a second offset value of the second etalon transfer curve based on the second peak frequency value Fₚₑₐₖ₂ and the second bottom frequency value F_{bottom2} (e.g., by using Equations 4 and 5). The calibration circuit 212 may calculate a third frequency fit value F_{fit3} based on the second peak frequency value Fₚₑₐₖ₂, the second FSR, and the second offset value in accordance with Equation 6, where frequency f is equal to the second peak frequency value Fₚₑₐₖ₂ (e.g., f=Fₚₑₐₖ₂). Additionally, the calibration circuit 212 may calculate a fourth frequency fit value F_{fit4} based on the second bottom frequency value F_{bottom2}, the second FSR, and the second offset value in accordance with Equation 6, where frequency f is equal to the second bottom frequency value F_{bottom2} (e.g., f=F_{bottom2}).

In addition, the calibration circuit 212 may calculate a third reciprocal value Y₃ representative of a reciprocal of the second maximum lock ratio, and may calculate a fourth reciprocal value Y₄ representative of a reciprocal of the second minimum lock ratio.

The calibration circuit 212 may calculate a second set of fit factor parameters (a₂, b₂) of a second line by performing a second linear fit to the line equation (e.g., a linear fit to Equation 11) using the third frequency fit value F_{fit2}, the third reciprocal value Y₃, the fourth frequency fit value F_{fit4}, and the fourth reciprocal value Y₄. The second line may be a line or an approximate line that connects the two measurement points of the second etalon transfer curve. Thus, the second set of fit factor parameters (a₂, b₂) includes a slope parameter a₂ representative of a slope of the second line and an intercept parameter b₂ representative of a y-axis intercept of the second line. Thus, the second set of fit factor parameters (a₂, b₂) correspond to a slope of the second etalon transfer curve.

The calibration circuit 212 may be configured to store the second set of fit factor parameters (a₂, b₂) in the memory device 230 and/or the memory device 234 as calibration information corresponding to the second etalon. For example, the calibration circuit 212 may store, into the memory device 230 and/or the memory device 234, the second set of fit factor parameters (a₂, b₂), the second FSR, the second offset value, and a frequency range defined by the second peak frequency value Fₚₑₐₖ₂ and the second bottom frequency value F_{bottom2} as linked parameters that correspond to the slope of the second etalon transfer curve.

The second set of fit factor parameters (a₂, b₂) may be used during a frequency lock operation of the second etalon. For example, the second set of fit factor parameters (a₂, b₂) may be used to determine a target lock ratio for a target frequency value F_{target}, and the target lock ratio may then be used by the controller 214 to perform the frequency lock operation. The target frequency value is located in the frequency range defined by the second peak frequency value Fₚₑₐₖ₂ and the second bottom frequency value F_{bottom2}. The calibration circuit 212 may be configured to calculate a corresponding set of fit factor parameters (a, b) for each slope of the second etalon transfer curve (e.g., for each slope between each pair of maximum and minimum LR values of the second etalon transfer curve), with each slope extending from a corresponding peak frequency value to a corresponding bottom frequency value. The calibration circuit 212 may store, into the memory device 230 and/or the memory device 234, each corresponding set of fit factor parameters (a, b) with a corresponding FSR, a corresponding offset value, and a corresponding frequency range as linked parameters that correspond to a respective slope of the second etalon transfer curve. For use in calculating the target lock ratio for a frequency lock operation, the calibration circuit 212 may look up the corresponding set of fit factor parameters (a, b), the corresponding FSR, and the corresponding offset value based on the corresponding frequency range in which the target frequency value F_{target} is located. The controller 214 may use the target lock ratio for the frequency lock operation of the second etalon as similarly described above in reference to the first etalon.

Although not represented in the drawings, the output light of the light sources of the light transmitter 202 may be divided into two or more portions, with only one portion directed into the frequency locker calibration system 200 for monitoring by a monitoring apparatus. In each case, the “beam” of one such portion is directed into the monitoring apparatus described herein, and the remaining portion(s) may be directed for useful output of a composite light source. The division of light into portions may occur for each discrete light source prior to being split for monitoring by the beam splitter 204. Alternatively, the light sources may have multiple outputs at a same wavelength, where one such output would provide the light to be directed to the monitoring apparatus. For the purpose of the implementations described herein, the portion of the beam directed to the monitoring apparatus can be any portion of a total beam. However, typically the portion of the beam directed to the monitoring apparatus would be a minority portion (e.g., 5%, 1%, 0.25%, etc.) of the total beam generated by the light source, with a larger portion of the total beam being directed to an output for useful output. Therefore, when it is stated that a light source generates a light beam and that the generated light beam is split or otherwise manipulated in the monitoring apparatus, the manipulated light beam may not comprise the total beam generated by the light source.

As indicated above, FIG. 2 is provided as an example. Other examples may differ from what is described with regard to FIG. 2.

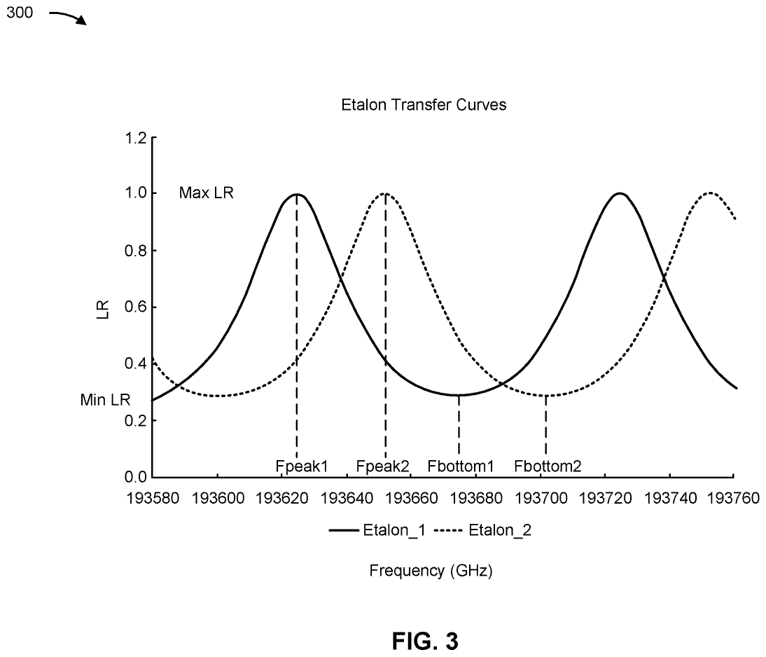

FIG. 3 shows a diagram 300 of etalon transfer curves for a stepped etalon according to one or more implementations. In particular, the diagram 300 shows a segment of a first etalon transfer curve for a first etalon of the stepped etalon and a segment of a second etalon transfer curve for a second etalon of the stepped etalon. The first etalon transfer curve and the second etalon transfer curve are offset from each other by a phase shift. The first etalon transfer curve and the second etalon transfer curve each have a same maximum LR and a same minimum LR, but the maximum LR and the minimum LR occur at different frequencies. For example, a maximum LR and a minimum LR of the first etalon transfer curve may occur at the first peak frequency value Fₚₑₐₖ₁ and the first bottom frequency value F_{bottom1}. Additional peak frequency values and additional bottom frequency values of the first etalon transfer curve may occur at the maximum LR and the minimum LR as a sinusoidal-like function. A maximum LR and a minimum LR of the second etalon transfer curve may occur at the second peak frequency value Fₚₑₐₖ₂ and the second bottom frequency value F_{bottom2}. Additional peak frequency values and additional bottom frequency values of the second etalon transfer curve may occur at the maximum LR and the minimum LR as a sinusoidal-like function. Thus, each peak frequency value is a resonant peak frequency, and each bottom frequency value is a minimum resonant frequency.

As indicated above, FIG. 3 is provided as an example. Other examples may differ from what is described with regard to FIG. 3.

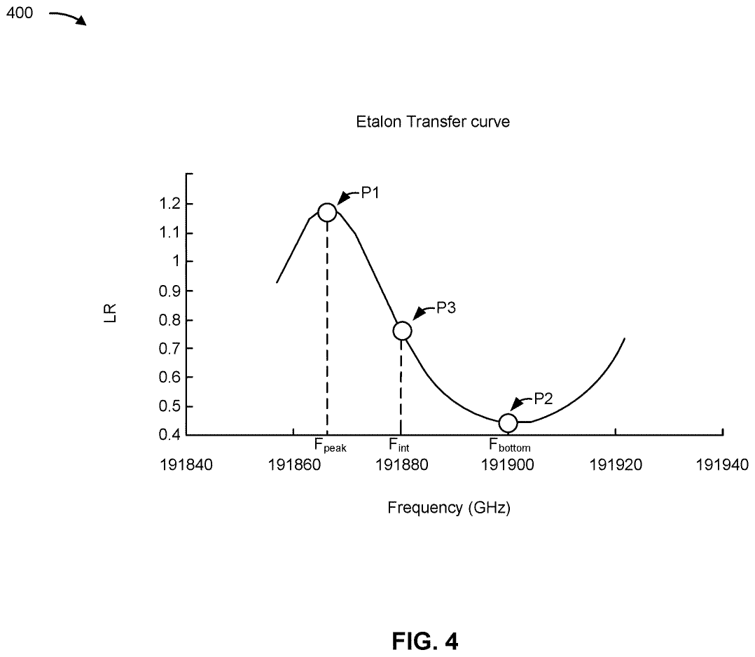

FIG. 4 shows an etalon transfer curve 400 corresponding to a stepped etalon calibration method according to one or more implementations. The stepped etalon calibration method includes changing one fitting formula for a whole band of the etalon transfer function curve to different fitting functions for different etalon slopes. The stepped etalon calibration method may include using two or more measurement points to perform a linear fit to a slope of the etalon transfer curve 400. In this example, a first measurement point P1 corresponds to the maximum LR, a second measurement point P2 corresponds to the minimum LR that is located one-half period from the first measurement point, and third measurement point P3 that is located on the etalon transfer curve 400 between the first measurement point P1 and the second measurement point P2. Since the maximum LR and the minimum LR may be predetermined (e.g., known), the calibration circuit 212 may perform a frequency sweep to determine the frequencies corresponding to the maximum LR and the minimum LR. Once the calibration circuit 212 determines the two frequencies corresponding to the maximum LR and the minimum LR, the calibration circuit 212 may select an intermediate frequency between the two frequencies to determine the LR corresponding to the intermediate frequency. Information obtained during these processes may be used for performing further processes of the stepped etalon calibration method, as similarly described above.

As indicated above, FIG. 4 is provided as an example. Other examples may differ from what is described with regard to FIG. 4.

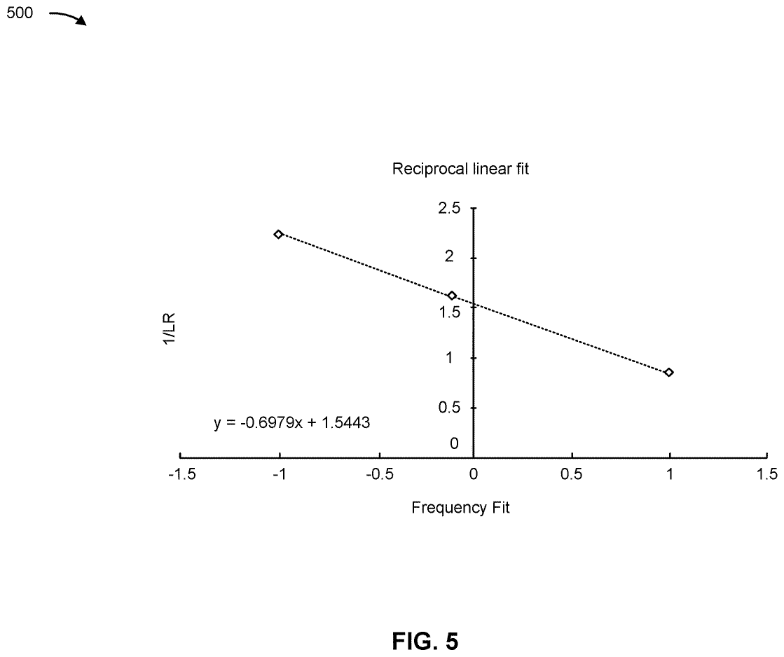

FIG. 5 shows a graph 500 of a reciprocal linear fit method of the stepped etalon calibration method according to one or more implementations. A slope segment of a sinusoidal-like etalon transfer curve is transformed into a straight line through reciprocal processing. For example, the straight line is estimated by performing the linear fit to a slope of the etalon transfer curve 400 using reciprocal processing based on a line equation (e.g., Equation 11). Equations 1-11 may be used, as described above, for performing the linear fit.

As indicated above, FIG. 5 is provided as an example. Other examples may differ from what is described with regard to FIG. 5.

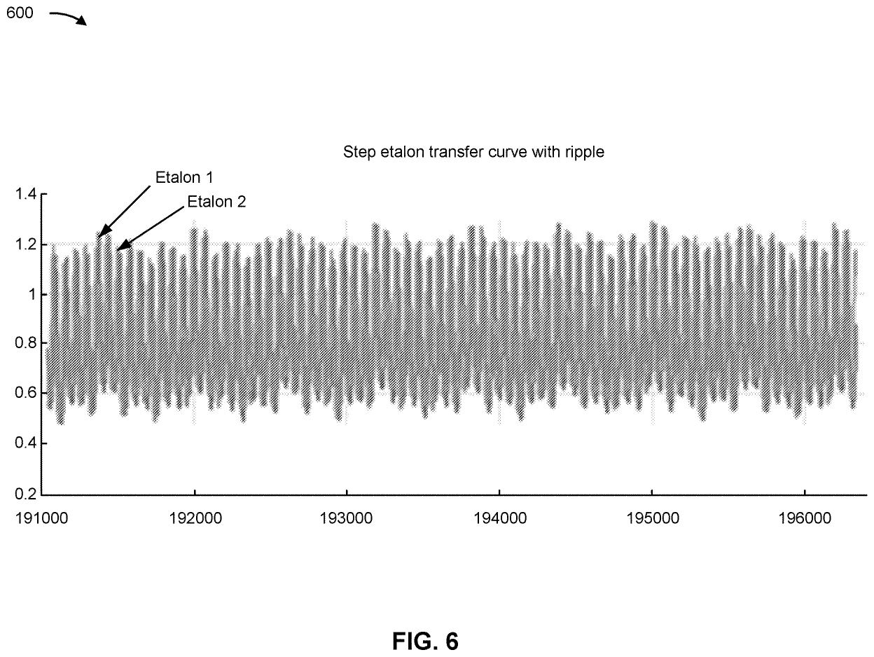

FIG. 6 shows a stepped etalon frequency response 600. The etalon frequency response 600 includes two etalon transfer curves, both of which contain ripple components. The etalon transfer curve for Etalon 2 is overlaid over the etalon transfer curve for Etalon 1. The ripple components make it difficult to estimate the two etalon transfer curves with a traditional fit calibration method.

As indicated above, FIG. 6 is provided as an example. Other examples may differ from what is described with regard to FIG. 6.

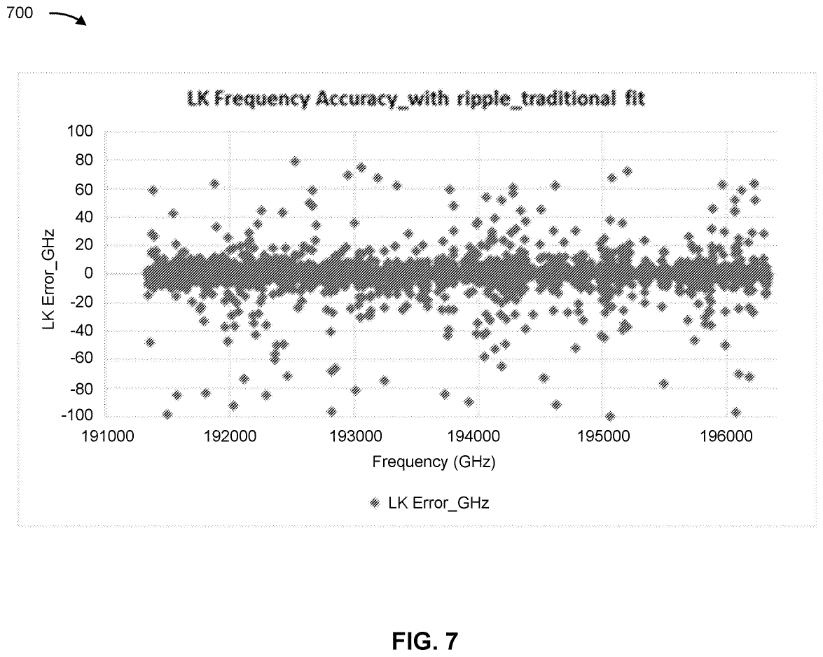

FIG. 7 shows a graph 700 of a lock frequency accuracy resultant from the stepped etalon transfer curve with ripples generated using a traditional fit calibration method. The graph 700 demonstrates that large locking errors (LK errors) occur when the traditional fit calibration method is used. For example, locking errors greatly exceeding 1 GHz are shown, with some errors equal to about 100 GHz. As a result, frequency locking based on the traditional fit calibration method leads to poor frequency locking performance.

As indicated above, FIG. 7 is provided as an example. Other examples may differ from what is described with regard to FIG. 7.

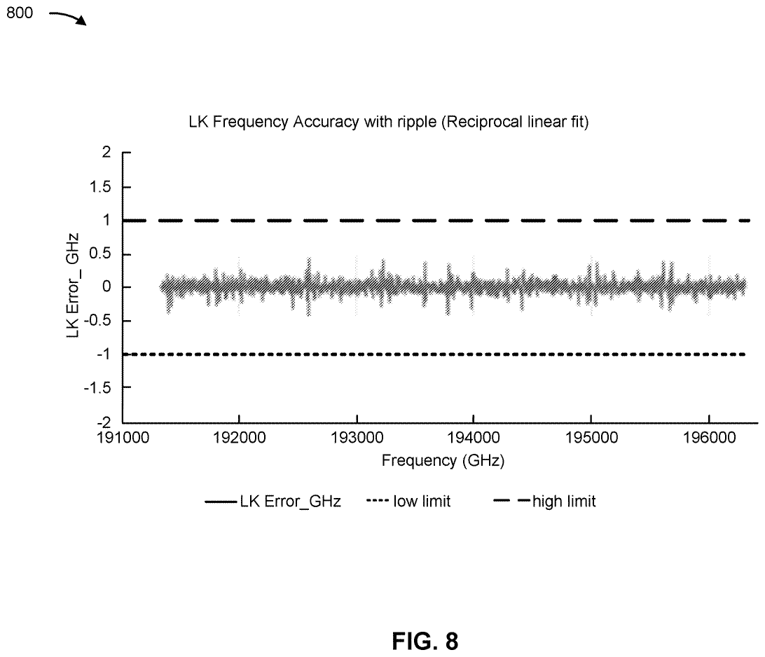

FIG. 8 shows a graph 800 of a lock frequency accuracy resultant from performing a calibration operation that uses the stepped etalon calibration method with the reciprocal linear fit method. Large errors may be prevented, as compared to the graph 700 described in connection with FIG. 7. For example, frequency errors (LK Error_GHz) may be smaller than 1.0 GHZ, designated by the low error limit and the high error limit. In other words, all frequency errors may be between −1.0 GHz and +1.0 GHz). In some cases, the frequency errors may be less than 0.5 GHz (e.g., all frequency errors may be between −0.5 GHz and +0.5 GHZ), as shown in FIG. 8. Thus, high performance in accuracy can be achieved with the stepped etalon calibration method described in reference to Equations 1-11. With this fit methodology, any half-FSR segment of an etalon transfer curve (e.g., any half-period between maximum and minimum etalon points) can be fit using limited test calibration data (e.g., two or more measurement points).

As indicated above, FIG. 8 is provided as an example. Other examples may differ from what is described with regard to FIG. 8.

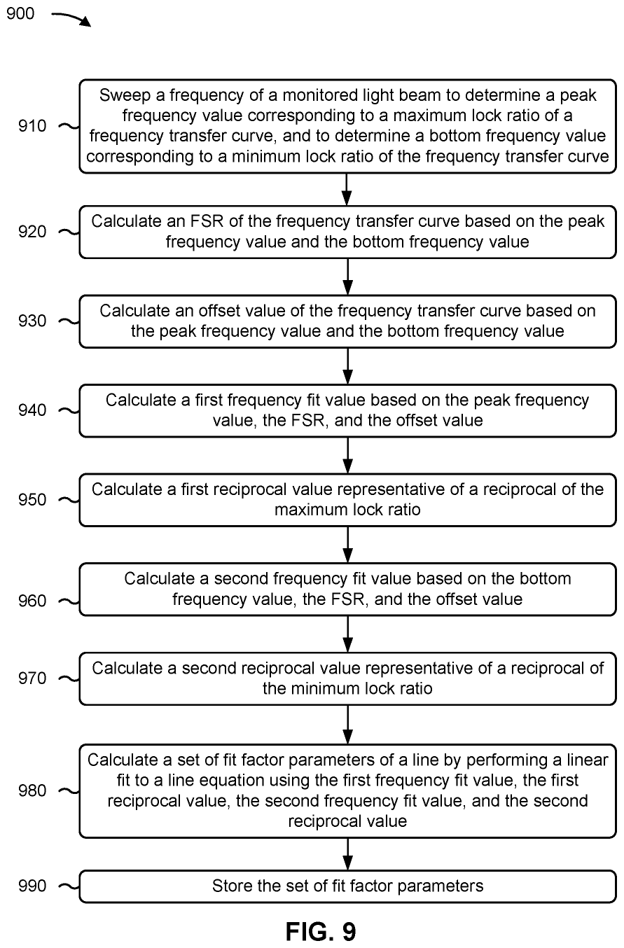

FIG. 9 is a flowchart of an example process 900 associated with a reciprocal linear fit methodology for calibrating a frequency locker. In some implementations, one or more process blocks of FIG. 9 are performed by a frequency locker calibration system (e.g., frequency locker calibration system 200). Additionally, or alternatively, one or more process blocks of FIG. 9 may be performed by one or more components of the frequency locker calibration system 200, such as the light transmitter 202, the beam splitter 204, the optical filter 206, the detector 208, the calibration circuit 212, and/or the controller 214.

As shown in FIG. 9, process 900 may include sweeping a frequency of a monitored light beam to determine a peak frequency value corresponding to a maximum lock ratio of a frequency transfer curve, and to determine a bottom frequency value corresponding to a minimum lock ratio of the frequency transfer curve (block 910). For example, the frequency locker calibration system 200 sweep the frequency of the monitored light beam to determine the peak frequency value corresponding to the maximum lock ratio of the frequency transfer curve, and to determine the bottom frequency value corresponding to the minimum lock ratio of the frequency transfer curve, as described above.

As further shown in FIG. 9, process 900 may include calculating an FSR of the frequency transfer curve based on the peak frequency value and the bottom frequency value (block 920). For example, the frequency locker calibration system 200 may calculate the FSR of the frequency transfer curve based on the peak frequency value and the bottom frequency value, as described above.

As further shown in FIG. 9, process 900 may include calculating an offset value of the frequency transfer curve based on the peak frequency value and the bottom frequency value (block 930). For example, the frequency locker calibration system 200 may calculate the offset value of the frequency transfer curve based on the peak frequency value and the bottom frequency value, as described above.

As further shown in FIG. 9, process 900 may include calculating a first frequency fit value based on the peak frequency value, the FSR, and the offset value (block 940). For example, the frequency locker calibration system 200 may calculate the first frequency fit value based on the peak frequency value, the FSR, and the offset value, as described above.

As further shown in FIG. 9, process 900 may include calculating a first reciprocal value representative of a reciprocal of the maximum lock ratio (block 950). For example, the frequency locker calibration system 200 may calculate the first reciprocal value representative of the reciprocal of the maximum lock ratio, as described above.

As further shown in FIG. 9, process 900 may include calculating a second frequency fit value based on the bottom frequency value, the FSR, and the offset value (block 960). For example, the frequency locker calibration system 200 may calculate the second frequency fit value based on the bottom frequency value, the FSR, and the offset value, as described above.

As further shown in FIG. 9, process 900 may include calculating a second reciprocal value representative of a reciprocal of the minimum lock ratio (block 970). For example, the frequency locker calibration system 200 may calculate the second reciprocal value representative of the reciprocal of the minimum lock ratio, as described above.

As further shown in FIG. 9, process 900 may include calculating a set of fit factor parameters of a line by performing a linear fit to a line equation using the first frequency fit value, the first reciprocal value, the second frequency fit value, and the second reciprocal value (block 980). For example, the frequency locker calibration system 200 may calculate the set of fit factor parameters of the line by performing the linear fit to the line equation using the first frequency fit value, the first reciprocal value, the second frequency fit value, and the second reciprocal value, as described above. A reciprocal linear fit calculation may include performing blocks 920-980.

As further shown in FIG. 9, process 900 may include storing the set of fit factor parameters (block 990). For example, the frequency locker calibration system 200 may store the set of fit factor parameters, as described above. The set of fit factor parameters may correspond to a slope of the frequency transfer curve.

Process 900 may include additional implementations, such as any single implementation or any combination of implementations described below and/or in connection with one or more other processes described elsewhere herein.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

The following provides an overview of some Aspects of the present disclosure:
Aspect 1: A frequency locker calibration system, comprising: at least one light source configured to generate a first light beam; a beam splitter configured to split the first light beam into a first monitored light beam, comprising a first portion of the first light beam, and a first reference light beam, comprising a second portion of the first light beam; an optical filter comprising a first etalon characterized by a first etalon transfer curve, wherein the first etalon transfer curve comprises a first plurality of resonant peak frequencies at which a first transmittivity of the first etalon is at a first maximum transmission level, and a first plurality of minimum resonant frequencies at which the first transmittivity of the first etalon is at a first minimum transmission level, wherein the first etalon is configured to receive the first monitored light beam and output the first monitored light beam as a first monitored output light beam according to the first etalon transfer curve; a detector configured to measure a first monitored intensity of the first monitored output light beam and a first reference intensity of the first reference light beam, and determine a first lock ratio representative of a ratio of the first monitored intensity and the first reference intensity; and a calibration circuit, comprising at least one processor, configured to control the at least one light source to adjust a frequency of the first light beam to estimate the first etalon transfer curve based on the first lock ratio, wherein the calibration circuit is configured to: sweep the frequency of the first light beam for determining a first peak frequency value corresponding to a first maximum lock ratio of the first etalon transfer curve, and for determining a first bottom frequency value corresponding to a first minimum lock ratio of the first etalon transfer curve, perform a first reciprocal linear fit calculation to calculate a first set of fit factor parameters of a first line based on the first peak frequency value and the first bottom frequency value, and store the first set of fit factor parameters, wherein the first set of fit factor parameters correspond to a first slope of the first etalon transfer curve.
Aspect 2: The frequency locker calibration system of Aspect 1, wherein the first set of fit factor parameters includes a slope parameter representative of a slope of the first line and an intercept parameter representative of a y-axis intercept of the first line.
Aspect 3: The frequency locker calibration system of any of Aspects 1-2, wherein the calibration circuit is configured to perform the first reciprocal linear fit calculation by: calculating a first FSR of the first etalon transfer curve and a first offset value of the first etalon transfer curve based on the first peak frequency value and the first bottom frequency value, calculating a first frequency fit value based on the first peak frequency value, the first FSR, and the first offset value, calculating a first reciprocal value representative of a reciprocal of the first maximum lock ratio, calculating a second frequency fit value based on the first bottom frequency value, the first FSR, and the first offset value, calculating a second reciprocal value representative of a reciprocal of the first minimum lock ratio, and calculating the first set of fit factor parameters of the first line by performing a first linear fit to a line equation using the first frequency fit value, the first reciprocal value, the second frequency fit value, and the second reciprocal value.
Aspect 4: The frequency locker calibration system of Aspect 3, wherein the calibration circuit is configured to store, into a memory device, the first set of fit factor parameters, the first FSR, the first offset value, and a frequency range defined by the first peak frequency value and the first bottom frequency value as linked parameters that correspond to the first slope of the first etalon transfer curve.
Aspect 5: The frequency locker calibration system of Aspect 4, wherein the calibration circuit is configured to calculate a target lock ratio for a target frequency value, including: calculating a target frequency fit value based on the target frequency value, the first FSR, and the first offset value, and calculating the target lock ratio based on the target frequency fit value and the first set of fit factor parameters, wherein the target frequency value is located in the frequency range.
Aspect 6: The frequency locker calibration system of Aspect 5, further comprising: a controller configured to receive the first lock ratio during a frequency lock operation, wherein the controller is configured to, during the frequency lock operation, tune the frequency of the first light beam to the target frequency value based on the first lock ratio such that a difference between the first lock ratio and the target lock ratio is minimized.
Aspect 7: The frequency locker calibration system of any of Aspects 1-6, wherein the first line is a first order line.
Aspect 8: The frequency locker calibration system of Aspect 3, wherein the calibration circuit is configured to: set the frequency of the first light beam to an intermediate frequency value between the first peak frequency value and the first bottom frequency value, measure the first lock ratio corresponding to the intermediate frequency value as an intermediate lock ratio, perform the first reciprocal linear fit calculation to calculate the first set of fit factor parameters of the first line based on the first peak frequency value, the first bottom frequency value, the intermediate frequency value, and the intermediate lock ratio.
Aspect 9: The frequency locker calibration system of Aspect 8, wherein the calibration circuit is configured to perform the first reciprocal linear fit calculation by: calculating a third frequency fit value based on the intermediate frequency value, the first FSR, and the first offset value, calculating a third reciprocal value representative of a reciprocal of the intermediate lock ratio, and calculating the first set of fit factor parameters of the first line by performing the first linear fit to the line equation using the first frequency fit value, the first reciprocal value, the second frequency fit value, the second reciprocal value, the third frequency fit value, and the third reciprocal value.
Aspect 10: The frequency locker calibration system of Aspect 9, wherein the first line is a higher order line of a second order or higher.
Aspect 11: The frequency locker calibration system of any of Aspects 1-10, wherein the calibration circuit is configured to calculate a corresponding set of fit factor parameters for each slope of the first etalon transfer curve, and wherein each slope extends from a corresponding peak frequency value to a corresponding bottom frequency value.
Aspect 12: The frequency locker calibration system of Aspect 3, wherein the at least one light source is configured to generate a second light beam, wherein the beam splitter is configured to split the second light beam into a second monitored light beam, comprising a first portion of the second light beam, and a second reference light beam, comprising a second portion of the second light beam, wherein the optical filter is a stepped etalon comprising a second etalon characterized by a second etalon transfer curve, wherein the second etalon is configured to receive the second monitored light beam and output the second monitored light beam as a second monitored output light beam according to the second etalon transfer curve, wherein the second etalon transfer curve comprises a second plurality of resonant peak frequencies at which a second transmittivity of the second etalon is at a second maximum transmission level, and a second plurality of minimum resonant frequencies at which the second transmittivity of the second etalon is at a second minimum transmission level, and wherein the second etalon transfer curve has a peak frequency offset relative to the first etalon transfer curve, wherein the detector is configured to measure a second monitored intensity of the second monitored output light beam and a second reference intensity of the second reference light beam, and determine a second lock ratio representative of a ratio of the second monitored intensity and the second reference intensity, wherein the calibration circuit is configured to control the at least one light source to adjust a frequency of the second light beam to estimate the second etalon transfer curve based on the second lock ratio, wherein the calibration circuit is configured to: sweep the frequency of the second light beam for determining a second peak frequency value corresponding to a second maximum lock ratio of the second etalon transfer curve, and for determining a second bottom frequency value corresponding to a second minimum lock ratio of the second etalon transfer curve, perform a second reciprocal linear fit calculation to calculate a second set of fit factor parameters of a second line based on the second peak frequency value and the second bottom frequency value, and store the second set of fit factor parameters, wherein the second set of fit factor parameters correspond to a second slope of the second etalon transfer curve.
Aspect 13: The frequency locker calibration system of Aspect 12, wherein the calibration circuit is configured to calculate a corresponding set of second factor parameters for each slope of the second etalon transfer curve, and wherein each slope extends from a corresponding peak frequency value to a corresponding bottom frequency value.
Aspect 14: The frequency locker calibration system of Aspect 12, wherein the calibration circuit is configured to perform the second reciprocal linear fit calculation by: calculating a second FSR of the second etalon transfer curve and a second offset value of the second etalon transfer curve based on the second peak frequency value and the second bottom frequency value, calculating a third frequency fit value based on the second peak frequency value, the second FSR, and the second offset value, calculating a third reciprocal value representative of a reciprocal of the second maximum lock ratio, calculating a fourth frequency fit value based on the second bottom frequency value, the second FSR, and the second offset value, calculating a fourth reciprocal value representative of a reciprocal of the second minimum lock ratio, and calculating the second set of fit factor parameters of the second line by performing a second linear fit to the line equation using the third frequency fit value, the third reciprocal value, the fourth frequency fit value, and the fourth reciprocal value.
Aspect 15: A frequency locker calibration system, comprising: a detector configured to measure a lock ratio of an interferometer, wherein the lock ratio is representative of a ratio of a monitored intensity of a monitored light beam that interacts with the interferometer and a reference intensity of a reference light beam that bypasses the interferometer, and wherein the interferometer is characterized by a frequency transfer curve; and a calibration circuit configured to adjust a frequency of the monitored light beam to estimate the frequency transfer curve based on the lock ratio, wherein the calibration circuit is configured to: sweep the frequency of the monitored light beam to determine a peak frequency value corresponding to a maximum lock ratio of the frequency transfer curve, and to determine a bottom frequency value corresponding to a minimum lock ratio of the frequency transfer curve, perform a reciprocal linear fit calculation to calculate a set of fit factor parameters of a line based on the peak frequency value and the bottom frequency value, and store the set of fit factor parameters, wherein the set of fit factor parameters correspond to a slope of the frequency transfer curve.
Aspect 16: The frequency locker calibration system of Aspect 15, wherein the calibration circuit is configured to perform the reciprocal linear fit calculation by: calculating an FSR of the frequency transfer curve and an offset value of the frequency transfer curve based on the peak frequency value and the bottom frequency value, calculating a first frequency fit value based on the peak frequency value, the FSR, and the offset value, calculating a first reciprocal value representative of a reciprocal of the maximum lock ratio, calculating a second frequency fit value based on the bottom frequency value, the FSR, and the offset value, calculating a second reciprocal value representative of a reciprocal of the minimum lock ratio, and calculating the set of fit factor parameters of the line by performing a linear fit to a line equation using the first frequency fit value, the first reciprocal value, the second frequency fit value, and the second reciprocal value.
Aspect 17: The frequency locker calibration system of any of Aspects 15-16, wherein the set of fit factor parameters includes a slope parameter representative of a slope of the line and an intercept parameter representative of a y-axis intercept of the line.
Aspect 18: The frequency locker calibration system of Aspect 16, wherein the calibration circuit is configured to store, into a memory device, the set of fit factor parameters, the FSR, the offset value, and a frequency range defined by the peak frequency value and the bottom frequency value as linked parameters that correspond to the slope of the frequency transfer curve.
Aspect 19: The frequency locker calibration system of Aspect 18, wherein the calibration circuit is configured to calculate a target lock ratio for a target frequency value, including: calculating a target frequency fit value based on the target frequency value, the FSR, and the offset value, and calculating the target lock ratio based on the target frequency fit value and the set of fit factor parameters, wherein the target frequency value is located in the frequency range.
Aspect 20: The frequency locker calibration system of any of Aspects 15-19, wherein the line is a first order line.
Aspect 20: The frequency locker calibration system of any of Aspects 15-20, wherein the line is a first order line.
Aspect 21: The frequency locker calibration system of Aspect 16, wherein the calibration circuit is configured to: set the frequency to an intermediate frequency value between the peak frequency value and the bottom frequency value, measure the lock ratio corresponding to the intermediate frequency value as an intermediate lock ratio, and perform the reciprocal linear fit calculation to calculate the set of fit factor parameters of the line based on the peak frequency value, the bottom frequency value, the intermediate frequency value, and the intermediate lock ratio.
Aspect 22: The frequency locker calibration system of Aspect 21, wherein the calibration circuit is configured to perform the reciprocal linear fit calculation by: calculating a third frequency fit value based on the intermediate frequency value, the FSR, and the offset value, calculating a third reciprocal value representative of a reciprocal of the intermediate lock ratio, and calculating the set of fit factor parameters of the line by performing the linear fit to the line equation using the first frequency fit value, the first reciprocal value, the second frequency fit value, the second reciprocal value, the third frequency fit value, and the third reciprocal value.
Aspect 23: The frequency locker calibration system of Aspect 22, wherein the line is a higher order line of a second order or higher.
Aspect 24: The frequency locker calibration system of any of Aspects 15-23, wherein the calibration circuit is configured to calculate a corresponding set of fit factor parameters for each slope of the frequency transfer curve, and wherein each slope extends from a corresponding peak frequency value to a corresponding bottom frequency value.
Aspect 25: A method of estimating a frequency transfer curve of an interferometer, the method comprising: measuring a lock ratio of an interferometer, wherein the lock ratio is representative of a ratio of a monitored intensity of a monitored light beam that interacts with the interferometer and a reference intensity of a reference light beam that bypasses the interferometer, and wherein the interferometer is characterized by the frequency transfer curve; adjusting the frequency of the monitored light beam to estimate the frequency transfer curve based on the lock ratio, including sweeping the frequency of the monitored light beam to determine a peak frequency value corresponding to a maximum lock ratio of the frequency transfer curve, and to determine a bottom frequency value corresponding to a minimum lock ratio of the frequency transfer curve; executing a reciprocal linear fit calculation to calculate a set of fit factor parameters of a line based on the peak frequency value and the bottom frequency value; and storing the set of fit factor parameters, wherein the set of fit factor parameters correspond to a slope of the frequency transfer curve.
Aspect 26: The method of Aspect 25, wherein executing the reciprocal linear fit calculation comprises: calculating an FSR of the frequency transfer curve based on the peak frequency value and the bottom frequency value; calculating an offset value of the frequency transfer curve based on the peak frequency value and the bottom frequency value; calculating a first frequency fit value based on the peak frequency value, the FSR, and the offset value; calculating a first reciprocal value representative of a reciprocal of the maximum lock ratio; calculating a second frequency fit value based on the bottom frequency value, the FSR, and the offset value; calculating a second reciprocal value representative of a reciprocal of the minimum lock ratio; and calculating the set of fit factor parameters of the line by performing a linear fit to a line equation using the first frequency fit value, the first reciprocal value, the second frequency fit value, and the second reciprocal value.
Aspect 27: A system configured to perform one or more operations recited in one or more of Aspects 1-26.
Aspect 28: An apparatus comprising means for performing one or more operations recited in one or more of Aspects 1-26.
Aspect 29: A non-transitory computer-readable medium storing a set of instructions, the set of instructions comprising one or more instructions that, when executed by a device, cause the device to perform one or more operations recited in one or more of Aspects 1-26.
Aspect 30: A computer program product comprising instructions or code for executing one or more operations recited in one or more of Aspects 1-26.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A frequency locker calibration system, comprising:
at least one light source configured to generate a first light beam;
a beam splitter configured to split the first light beam into a first monitored light beam, comprising a first portion of the first light beam, and a first reference light beam, comprising a second portion of the first light beam;
an optical filter comprising a first etalon characterized by a first etalon transfer curve,
wherein the first etalon transfer curve comprises a first plurality of resonant peak frequencies at which a first transmittivity of the first etalon is at a first maximum transmission level, and a first plurality of minimum resonant frequencies at which the first transmittivity of the first etalon is at a first minimum transmission level,
wherein the first etalon is configured to receive the first monitored light beam and output the first monitored light beam as a first monitored output light beam according to the first etalon transfer curve;
a detector configured to measure a first monitored intensity of the first monitored output light beam and a first reference intensity of the first reference light beam, and determine a first lock ratio representative of a ratio of the first monitored intensity and the first reference intensity; and
a calibration circuit, comprising at least one processor, configured to control the at least one light source to adjust a frequency of the first light beam to estimate the first etalon transfer curve based on the first lock ratio,
wherein the calibration circuit is configured to:
sweep the frequency of the first light beam for determining a first peak frequency value corresponding to a first maximum lock ratio of the first etalon transfer curve, and for determining a first bottom frequency value corresponding to a first minimum lock ratio of the first etalon transfer curve,
perform a first reciprocal linear fit calculation to calculate a first set of fit factor parameters of a first line based on the first peak frequency value and the first bottom frequency value, and
store the first set of fit factor parameters, wherein the first set of fit factor parameters correspond to a first slope of the first etalon transfer curve.

2. The frequency locker calibration system of claim 1, wherein the first set of fit factor parameters includes a slope parameter representative of a slope of the first line and an intercept parameter representative of a y-axis intercept of the first line.

3. The frequency locker calibration system of claim 1, wherein the calibration circuit is configured to perform the first reciprocal linear fit calculation by:
calculating a first free spectral range (FSR) of the first etalon transfer curve and a first offset value of the first etalon transfer curve based on the first peak frequency value and the first bottom frequency value,
calculating a first frequency fit value based on the first peak frequency value, the first FSR, and the first offset value,
calculating a first reciprocal value representative of a reciprocal of the first maximum lock ratio,
calculating a second frequency fit value based on the first bottom frequency value, the first FSR, and the first offset value,
calculating a second reciprocal value representative of a reciprocal of the first minimum lock ratio, and
calculating the first set of fit factor parameters of the first line by performing a first linear fit to a line equation using the first frequency fit value, the first reciprocal value, the second frequency fit value, and the second reciprocal value.

4. The frequency locker calibration system of claim 3, wherein the calibration circuit is configured to store, into a memory device, the first set of fit factor parameters, the first FSR, the first offset value, and a frequency range defined by the first peak frequency value and the first bottom frequency value as linked parameters that correspond to the first slope of the first etalon transfer curve.

5. The frequency locker calibration system of claim 4, wherein the calibration circuit is configured to calculate a target lock ratio for a target frequency value, including:
calculating a target frequency fit value based on the target frequency value, the first FSR, and the first offset value, and
calculating the target lock ratio based on the target frequency fit value and the first set of fit factor parameters,
wherein the target frequency value is located in the frequency range.

6. The frequency locker calibration system of claim 5, further comprising:
a controller configured to receive the first lock ratio during a frequency lock operation,
wherein the controller is configured to, during the frequency lock operation, tune the frequency of the first light beam to the target frequency value based on the first lock ratio such that a difference between the first lock ratio and the target lock ratio is minimized.

7. The frequency locker calibration system of claim 1, wherein the first line is a first order line.

8. The frequency locker calibration system of claim 3, wherein the calibration circuit is configured to:
set the frequency of the first light beam to an intermediate frequency value between the first peak frequency value and the first bottom frequency value,
measure the first lock ratio corresponding to the intermediate frequency value as an intermediate lock ratio,
perform the first reciprocal linear fit calculation to calculate the first set of fit factor parameters of the first line based on the first peak frequency value, the first bottom frequency value, the intermediate frequency value, and the intermediate lock ratio.

9. The frequency locker calibration system of claim 8, wherein the calibration circuit is configured to perform the first reciprocal linear fit calculation by:
calculating a third frequency fit value based on the intermediate frequency value, the first FSR, and the first offset value,
calculating a third reciprocal value representative of a reciprocal of the intermediate lock ratio, and
calculating the first set of fit factor parameters of the first line by performing the first linear fit to the line equation using the first frequency fit value, the first reciprocal value, the second frequency fit value, the second reciprocal value, the third frequency fit value, and the third reciprocal value.

10. The frequency locker calibration system of claim 9, wherein the first line is a higher order line of a second order or higher.

11. The frequency locker calibration system of claim 1, wherein the calibration circuit is configured to calculate a corresponding set of fit factor parameters for each slope of the first etalon transfer curve, and
wherein each slope extends from a corresponding peak frequency value to a corresponding bottom frequency value.

12. The frequency locker calibration system of claim 3, wherein the at least one light source is configured to generate a second light beam,
wherein the beam splitter is configured to split the second light beam into a second monitored light beam, comprising a first portion of the second light beam, and a second reference light beam, comprising a second portion of the second light beam,
wherein the optical filter is a stepped etalon comprising a second etalon characterized by a second etalon transfer curve,
wherein the second etalon is configured to receive the second monitored light beam and output the second monitored light beam as a second monitored output light beam according to the second etalon transfer curve,
wherein the second etalon transfer curve comprises a second plurality of resonant peak frequencies at which a second transmittivity of the second etalon is at a second maximum transmission level, and a second plurality of minimum resonant frequencies at which the second transmittivity of the second etalon is at a second minimum transmission level, and wherein the second etalon transfer curve has a peak frequency offset relative to the first etalon transfer curve,
wherein the detector is configured to measure a second monitored intensity of the second monitored output light beam and a second reference intensity of the second reference light beam, and determine a second lock ratio representative of a ratio of the second monitored intensity and the second reference intensity,
wherein the calibration circuit is configured to control the at least one light source to adjust a frequency of the second light beam to estimate the second etalon transfer curve based on the second lock ratio,
wherein the calibration circuit is configured to:
sweep the frequency of the second light beam for determining a second peak frequency value corresponding to a second maximum lock ratio of the second etalon transfer curve, and for determining a second bottom frequency value corresponding to a second minimum lock ratio of the second etalon transfer curve,
perform a second reciprocal linear fit calculation to calculate a second set of fit factor parameters of a second line based on the second peak frequency value and the second bottom frequency value, and
store the second set of fit factor parameters, wherein the second set of fit factor parameters correspond to a second slope of the second etalon transfer curve.

13. The frequency locker calibration system of claim 12, wherein the calibration circuit is configured to calculate a corresponding set of second factor parameters for each slope of the second etalon transfer curve, and
wherein each slope extends from a corresponding peak frequency value to a corresponding bottom frequency value.

14. The frequency locker calibration system of claim 12, wherein the calibration circuit is configured to perform the second reciprocal linear fit calculation by:
calculating a second FSR of the second etalon transfer curve and a second offset value of the second etalon transfer curve based on the second peak frequency value and the second bottom frequency value,
calculating a third frequency fit value based on the second peak frequency value, the second FSR, and the second offset value,
calculating a third reciprocal value representative of a reciprocal of the second maximum lock ratio,
calculating a fourth frequency fit value based on the second bottom frequency value, the second FSR, and the second offset value,
calculating a fourth reciprocal value representative of a reciprocal of the second minimum lock ratio, and
calculating the second set of fit factor parameters of the second line by performing a second linear fit to the line equation using the third frequency fit value, the third reciprocal value, the fourth frequency fit value, and the fourth reciprocal value.

15. A frequency locker calibration system, comprising:
a detector configured to measure a lock ratio of an interferometer, wherein the lock ratio is representative of a ratio of a monitored intensity of a monitored light beam that interacts with the interferometer and a reference intensity of a reference light beam that bypasses the interferometer, and wherein the interferometer is characterized by a frequency transfer curve; and
a calibration circuit configured to adjust a frequency of the monitored light beam to estimate the frequency transfer curve based on the lock ratio,
wherein the calibration circuit is configured to:
sweep the frequency of the monitored light beam to determine a peak frequency value corresponding to a maximum lock ratio of the frequency transfer curve, and to determine a bottom frequency value corresponding to a minimum lock ratio of the frequency transfer curve,
perform a reciprocal linear fit calculation to calculate a set of fit factor parameters of a line based on the peak frequency value and the bottom frequency value, and
store the set of fit factor parameters, wherein the set of fit factor parameters correspond to a slope of the frequency transfer curve.

16. The frequency locker calibration system of claim 15, wherein the calibration circuit is configured to perform the reciprocal linear fit calculation by:
calculating a free spectral range (FSR) of the frequency transfer curve and an offset value of the frequency transfer curve based on the peak frequency value and the bottom frequency value,
calculating a first frequency fit value based on the peak frequency value, the FSR, and the offset value,
calculating a first reciprocal value representative of a reciprocal of the maximum lock ratio,
calculating a second frequency fit value based on the bottom frequency value, the FSR, and the offset value,
calculating a second reciprocal value representative of a reciprocal of the minimum lock ratio, and
calculating the set of fit factor parameters of the line by performing a linear fit to a line equation using the first frequency fit value, the first reciprocal value, the second frequency fit value, and the second reciprocal value.

17. The frequency locker calibration system of claim 15, wherein the set of fit factor parameters includes a slope parameter representative of a slope of the line and an intercept parameter representative of a y-axis intercept of the line.

18. The frequency locker calibration system of claim 16, wherein the calibration circuit is configured to store, into a memory device, the set of fit factor parameters, the FSR, the offset value, and a frequency range defined by the peak frequency value and the bottom frequency value as linked parameters that correspond to the slope of the frequency transfer curve.

19. The frequency locker calibration system of claim 18, wherein the calibration circuit is configured to calculate a target lock ratio for a target frequency value, including:
calculating a target frequency fit value based on the target frequency value, the FSR, and the offset value, and
calculating the target lock ratio based on the target frequency fit value and the set of fit factor parameters,
wherein the target frequency value is located in the frequency range.

20. The frequency locker calibration system of claim 19, further comprising:
a controller configured to receive the lock ratio during a frequency lock operation,
wherein the controller is configured to, during the frequency lock operation, tune a frequency of a light source to the target frequency value based on the lock ratio such that a difference between the lock ratio and the target lock ratio is minimized.

21. The frequency locker calibration system of claim 15, wherein the line is a first order line.

22. The frequency locker calibration system of claim 16, wherein the calibration circuit is configured to:
set the frequency to an intermediate frequency value between the peak frequency value and the bottom frequency value,
measure the lock ratio corresponding to the intermediate frequency value as an intermediate lock ratio, and
perform the reciprocal linear fit calculation to calculate the set of fit factor parameters of the line based on the peak frequency value, the bottom frequency value, the intermediate frequency value, and the intermediate lock ratio.

23. The frequency locker calibration system of claim 22, wherein the calibration circuit is configured to perform the reciprocal linear fit calculation by:
calculating a third frequency fit value based on the intermediate frequency value, the FSR, and the offset value,
calculating a third reciprocal value representative of a reciprocal of the intermediate lock ratio, and
calculating the set of fit factor parameters of the line by performing the linear fit to the line equation using the first frequency fit value, the first reciprocal value, the second frequency fit value, the second reciprocal value, the third frequency fit value, and the third reciprocal value.

24. The frequency locker calibration system of claim 23, wherein the line is a higher order line of a second order or higher.

25. The frequency locker calibration system of claim 15, wherein the calibration circuit is configured to calculate a corresponding set of fit factor parameters for each slope of the frequency transfer curve, and
wherein each slope extends from a corresponding peak frequency value to a corresponding bottom frequency value.

26. A method of estimating a frequency transfer curve of an interferometer, the method comprising:
measuring a lock ratio of an interferometer, wherein the lock ratio is representative of a ratio of a monitored intensity of a monitored light beam that interacts with the interferometer and a reference intensity of a reference light beam that bypasses the interferometer, and wherein the interferometer is characterized by the frequency transfer curve;
adjusting the frequency of the monitored light beam to estimate the frequency transfer curve based on the lock ratio, including sweeping the frequency of the monitored light beam to determine a peak frequency value corresponding to a maximum lock ratio of the frequency transfer curve, and to determine a bottom frequency value corresponding to a minimum lock ratio of the frequency transfer curve;
executing a reciprocal linear fit calculation to calculate a set of fit factor parameters of a line based on the peak frequency value and the bottom frequency value; and
storing the set of fit factor parameters, wherein the set of fit factor parameters correspond to a slope of the frequency transfer curve.

27. The method of claim 26, wherein executing the reciprocal linear fit calculation comprises:
calculating a free spectral range (FSR) of the frequency transfer curve based on the peak frequency value and the bottom frequency value;
calculating an offset value of the frequency transfer curve based on the peak frequency value and the bottom frequency value;
calculating a first frequency fit value based on the peak frequency value, the FSR, and the offset value;
calculating a first reciprocal value representative of a reciprocal of the maximum lock ratio;
calculating a second frequency fit value based on the bottom frequency value, the FSR, and the offset value;
calculating a second reciprocal value representative of a reciprocal of the minimum lock ratio; and
calculating the set of fit factor parameters of the line by performing a linear fit to a line equation using the first frequency fit value, the first reciprocal value, the second frequency fit value, and the second reciprocal value.
